(19) United States
(12) Patent Application Publication
(10) Pub. No.: US 2015/0236136 A1
(43) Pub. Date: Aug. 20, 2015

(54) FLASH MEMORY CELL WITH FLOATING GATE WITH INCREASED SURFACE AREA

(71) Applicant: WaferTech, LLC, Camas, WA (US)

(72) Inventors: Re-Long CHIU, Vancouver, WA (US); Arthur CHIN, Vancouver, WA (US); Yun CHONG, Camas, WA (US); Delilah BERNABE, Vancouver, WA (US)

(73) Assignee: WaferTech, LLC, Camas, WA (US)

(21) Appl. No.: 14/181,197

(22) Filed: Feb. 14, 2014

(51) Int. Cl. H01L 29/66; H01L 21/311; H01L 29/788

(52) U.S. Cl. CPC H01L 29/66825; H01L 29/788; H01L 21/31138

(57) ABSTRACT

Provided are stacked gate floating gate transistors and split gate floating gate transistors having floating gates with respective upper surfaces that include upwardly extending pillars which are sharp, densely packed apices in some embodiments, and an increased surface area. The increased surface area enables lower erase voltages to be used and enables smaller device feature sizes, particularly for split gate floating gate transistors. A method for forming the floating gate is also provided, and includes using a polymeric or other sacrificial layer over a polysilicon layer, etching to remove most of the polymeric or other sacrificial layer but leaving residual specks on the polysilicon layer, the specks having sizes in the nanometer range. The residual specks serve as masking objects in a subsequent operation that forms the associated pillars by partially etching the polysilicon layer.

### TECHNICAL FIELD

The disclosure relates most generally to semiconductor manufacturing methods and semiconductor devices, and more particularly to floating gate flash memory cells with low erase voltages and methods for forming the same.

### BACKGROUND

A flash memory semiconductor device is a non-volatile storage device that can be electrically erased and reprogrammed. Flash memories are commonly used in memory cards, USB flash drives and solid-state drives for general storage and transfer of data between computers and other digital products. Flash memories typically store information in an array of memory cells made using floating gate transistors.

A floating gate transistor is a field effect transistor having a structure similar to a MOSFET (metal oxide semiconductor field effect transistor). Floating gate MOSFETs are distinguished from MOSFETs because the floating gate transistor includes two gates instead of one. In addition to an upper control gate, a floating gate transistor includes an additional floating gate between the control gate and above the transistor channel but completely electrically isolated by an insulating layer such as an oxide that completely surrounds the floating gate. This electrically isolated floating gate creates a floating node in DC with a number of inputs or secondary gates such as the control gate, formed above the floating gate and electrically isolated from it. These secondary gates or inputs are capacitively connected to the floating gate. Because the floating gate is completely surrounded by highly resistive material, i.e., an insulating layer, any charge placed on the floating gate is trapped there and the floating gate remains unchanged for long periods of time until the floating gate MOSFET is erased.

Unless erased, the floating gate will not discharge for many years under normal conditions. These devices, however, must often be erased.

The default state of an NOR flash cell is logically equivalent to a binary “one” value because current flows through the channel under application of an appropriate voltage to the control gate when charge is stored in the floating gate. Such a flash cell device can be programmed or set to binary “zero” by applying an elevated voltage to the control gate.

To erase such a flash cell, resetting it to the “one” state, a large voltage of the opposite polarity is applied between the control gate and the source causing electrons to exit the floating gate through quantum tunneling. In this manner, the electrical charge is removed from the floating gate. In stacked gate flash cells, i.e., when the control gate is directly over the floating gate, a high voltage is used to erase the flash cell. In split gate flash cells, i.e., flash cells in which the control gate is formed over part of the floating gate and is also disposed along the side and lateral to the floating gate, floating gate transistors with large feature sizes are used to provide a sufficiently large area between the two electrodes so that, when a voltage is applied, the transistor will be erased. For stacked gate flash cells, the high voltage levels are undesirable and can cause other problems such as shorting in the devices. In split gate flash cells, the large device features take up valuable space and reduce integration levels.

### BRIEF DESCRIPTION OF THE DRAWING

The present disclosure is best understood from the following detailed description when read in conjunction with the accompanying drawing. It is emphasized that, according to common practice, the various features of the drawing are not necessarily to scale. On the contrary, the dimensions of the various features are arbitrarily expanded or reduced for clarity. Like numerals denote like features throughout the specification and drawing.

FIGS. 1A-1G are cross-sectional views illustrating a sequence of processing operations used to form a stacked gate floating gate transistor according to various embodiments of the disclosure;

FIGS. 2A and 2B are cross-sectional views illustrating a roughened upper surface produced according to various embodiments of the disclosure;

FIGS. 3A-3F are cross-sectional views showing a illustrating of processing operations used to form a split gate floating gate transistor according to various embodiments of the disclosure; and

FIG. 4 is a plan view showing a floating gate with sharp apices and associated pillars according to various embodiments of the disclosure.

### DETAILED DESCRIPTION

Various embodiments of the disclosure provides flash memories with floating gate transistors that can be erased using relatively low voltages and split gate flash cell memory devices that do not require large critical dimensions in order to be erased.

Various embodiments of the disclosure provide floating gate transistors including both stacked gate floating gate transistors and split gate floating gate transistors. Some embodiments provides a floating gate electrode with an increased upper surface area and an upper surface area that is much greater than the corresponding lower surface area, i.e. much greater than the “footprint” of the floating gate. In some embodiments, the area of the upper surface is at least 300% of the area defined by the lateral dimensions of the floating gate electrode. This is attributable to sharp peaks, also referred to as apices throughout this disclosure, formed on the top surface, and pillars associated with the apices, according to various embodiments of the disclosure. In various other embodiments of the disclosure, the floating gate electrode includes an increased surface area with other surface configurations such as but not limited to pillars with flat top surfaces and having a generally rectangular shape or pillars with rounded tops or a generally roughened surface with increased surface area.

Because the upper surface of the floating gate electrode includes an increased surface area, stacked gate floating gate transistors can be erased using lower erase voltages. Further, split gate flash cell floating gate transistors do not require large device features because of the increased area that enables the flash cells to be erased using a voltage considerably less than necessary for erasing a floating gate transistor with a flat, smooth upper surface. Various embodiments of the disclosure provide methods for forming the stacked and split gate floating gate transistors by forming a polymer “grass” on the surface of the floating gate prior to carrying out an etching operation in which the polymer grass functions as a plurality of tiny masking objects that enable the production of the floating gate electrode with the roughened upper surface with sharp edges and therefore a greater surface area.

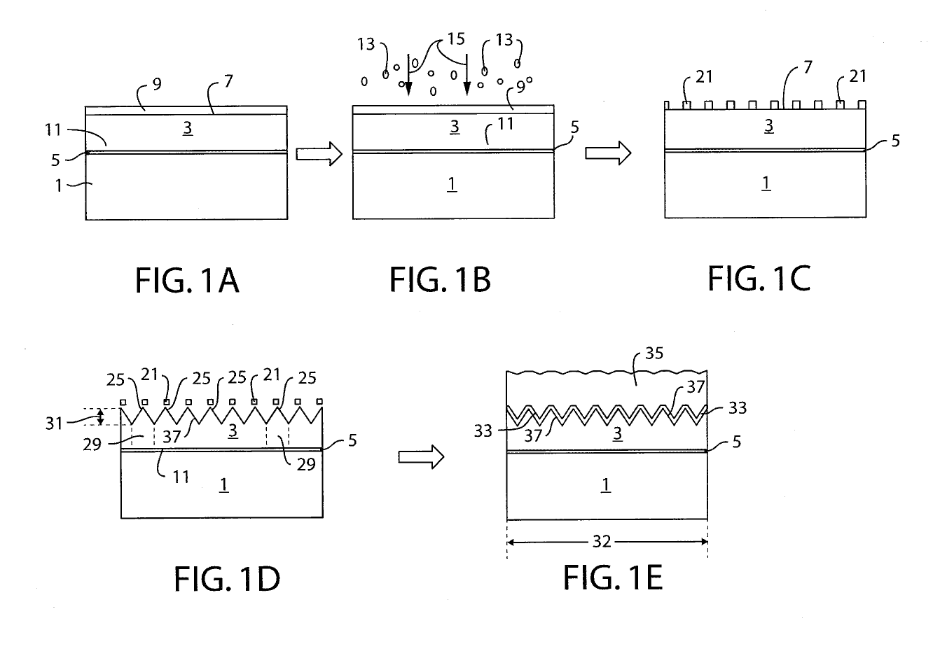

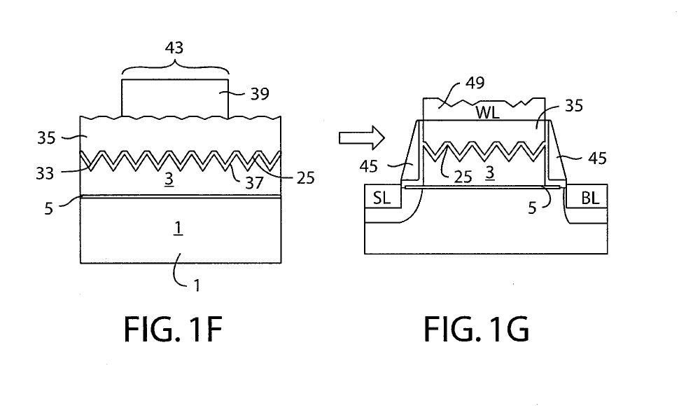

FIG. 1A is a cross-sectional view showing silicon layer 3 formed over substrate 1 also labeled as Si-sub. Gate dielectric 5 is disposed between silicon layer 3 and substrate 1. Substrate 1 is a silicon wafer in some embodiments and other suitable substrate materials used in the manufacture of semiconductor devices are used in other embodiments. Gate dielectric 5 is formed of various materials in various embodiments. Silicon layer 3 is polysilicon in some embodiments but other types of silicon are used in other embodiments. Silicon layer 3 is doped in some embodiments and is undoped in other embodiments. Silicon layer 3 includes a thickness ranging from about 50 nm to about 300 nm in some embodiments, but other thicknesses are used in other embodiments. Silicon layer 3 includes smooth top surface 7. Silicon layer 3 also includes smooth bottom surface 11 which includes a surface area equal to smooth top surface 7 and is considered the “footprint” of silicon layer 3. Smooth top surface 7 includes the same surface area as the footprint of silicon layer 3. Sacrificial layer 9 is formed over smooth top surface 7 of silicon layer 3. In some embodiments, sacrificial layer 9 is a polymer and in other embodiments, sacrificial layer 9 is formed of other suitable materials such as an oxide. In an embodiment, sacrificial layer 9 is photoresist, in another embodiment, sacrificial layer 9 is a uv-curable photosetting polymer and in another embodiment, sacrificial layer 9 is a thermoplastic polymer. Various other suitable materials are used for sacrificial layer 9 in other embodiments.

The thicknesses and other dimensions provided in the foregoing and following descriptions are according to various embodiments of the disclosure, but other thicknesses and dimensions are used in other embodiments. In each case, the dimensions are best suited to manufacturability, comply with design rules, and produce a device with maximized functionality and performance.

FIG. 1B shows an RIE (reactive ion etch) etching operation taking place upon the structure shown in FIG. 1A. The RIE etching operation is used to remove the bulk of sacrificial layer 9 while leaving residuals in the form of nanometer sized specks of sacrificial layer 9 on smooth top surface 7 of silicon layer 3. In the RIE process carried out in FIG. 1B, etchant species 13 are accelerated along direction 15 as determined by the applied bias and magnetic field. Various RIE etching operations are used in various embodiments and in some embodiments, the RIE process includes a pressure of about 100-300 millitorr, a power of about 200-400 watts and is carried out for a time ranging from about 30 seconds to about two minutes. In other embodiments, other pressures, powers and times are used. In an embodiment, the RIE process includes an HBr (hydrogen bromide) etching gas at a flow rate of 120 sccm (standard cubic centimeters per minute) and Cl₂ etching gas at a flow rate of about 10 sccm but other HBr and other Cl₂ flow rates are used in other embodiments. In still other embodiments, different halogen based etchant species or other etchant species are used depending on the nature of sacrificial layer 9. The RIE process also includes a magnetic field of 30 Gauss in an embodiment but the magnetic field (B-field) varies from about 10-50 Gauss in other embodiments. The magnetic field enhances plasma density therefore and increases dissociation of reactive species. Various plasma densities are used and the plasma density influences the spacing and concentration of the apices and pillars formed of silicon layer 3

FIG. 1C shows the structure of FIG. 1B after the RIE etching operation has been carried out. Specks 21 remain on smooth surface 7 of silicon layer 3. Specks 21 represent residuals of sacrificial layer 9 and in some embodiments, specks 21 have radii ranging from about several nanometers to about several hundred nanometers. In some embodiments, specks 21 are generally round in nature and are described with respect to their radii, but in other embodiments, specks 21 have different shapes and include lateral and vertical dimensions in the nanometer range, i.e. specks 21 may have diameters or widths ranging from about a few nanometers to about several hundred nanometers. Specks 21 are spaced apart by various spacings and are generally arranged in various random arrangements along smooth top surface 7.

These residual specks 21 serve as masking objects during an etching operation used to etch silicon layer 3 as will be shown in FIG. 1D.

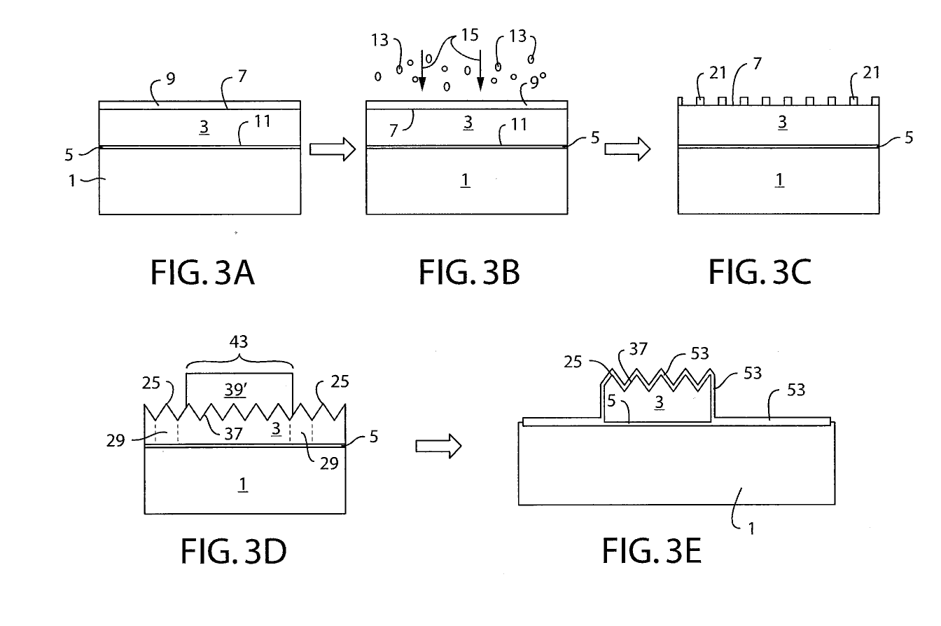

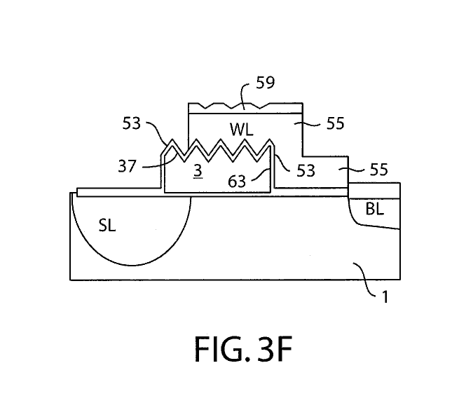

FIG. 1D shows the structure of FIG. 1C after an etching operation has been carried out to etch into silicon layer 3. Various RIE etching operations for etching silicon are used in various embodiments. Specks 21 serve as masking objects and the etching operation produces apices 25 as sharp jagged edges of silicon layer 3. Although shown as being regularly spaced in FIG. 1D, specks 21 and apices 25 are randomly spaced in various embodiments. Each of the apices 25 has an associated pillar 29 that terminates at respective apices 25. Pillars 29 take on different shapes and sizes and are not necessarily evenly spaced and shaped and identically sized, as in FIG. 1D. FIG. 1D is expanded for clarity and apices 25 and associated pillars 29 are also shown in the SEM micrograph of FIG. 3. The apices 25 and pillars 29 are formed from associated specks having dimensions ranging from a few nanometers to several hundred nanometers. As such, the apices are very small in size and may be referred to as “nanotips.” In some embodiments, depth 31 is about 50% of the original height of silicon layer 3 but depth 31 can vary from 25 to about 100% of the original thickness of silicon layer 3, in other embodiments. In some embodiments, pillars 29 have heights ranging from about 5 nm to about 300 nm but other heights are achieved and used in other embodiments. It can be seen that upper surface 37 of etched silicon layer 3, including apices 25 is greater than the surface area of bottom surface 11 of silicon layer 3.

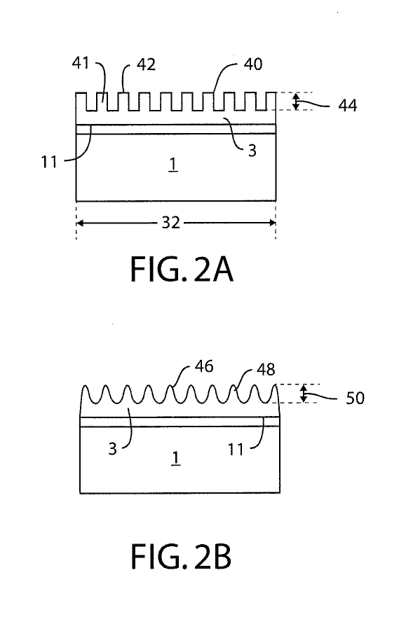

In various embodiments of the disclosure, the surface area of the upper surface such s upper surface 37 is at least 300% of the surface area defined by the lateral dimensions of silicon layer 3 and bottom surface 11. In various embodiments of the disclosure, upper surface 37 of etched silicon layer 3 includes a surface area that ranges from about 200-400% of the area defined by the lateral dimensions such as width 32 and an orthogonal lateral dimension (not shown) of silicon layer 3. In various other embodiments of the disclosure such as shown in FIGS. 2A-2B, silicon layer 3 has a roughened upper surface of other shapes and an increased surface area that ranges from about 200-400% of the area defined by the lateral dimensions such as width 32 and an orthogonal lateral dimension (not shown) of silicon layer 3.

FIG. 1E shows the structure of FIG. 1D after specks 21 have been removed by a cleaning operation and dielectric 33 and upper silicon layer 35 are formed over the structure in FIG. 1D after the cleaning. Various wet and dry cleaning operations are used to remove residual specks 21 after the etching operation illustrated in FIG. 1D. Dielectric 33 is an oxide or a nitride in some embodiments and in other embodiments, dielectric layer 33 is an ONO layer including a native oxide, a nitride layer over the native oxide and a top oxide layer. Various thicknesses are used. Dielectric 33 has a thickness ranging from about 2-50 or 2-100 nm in various embodiments but other thicknesses are used in other embodiments. Dielectric 33 is a conformal dielectric and includes a thickness chosen in conjunction with the surface morphology of upper surface 37 including apices 25 of etched silicon layer 3. In some embodiments, the top surface of the structure including etched silicon layer 3 and dielectric 33 is an uneven, jagged-edged surface but in other embodiments, dielectric 33 has a thickness sufficient to produce a relatively smooth upper surface of dielectric 33. Upper silicon layer 35 is formed over dielectric 33 and includes a thickness ranging from about 1,000 angstroms to about 3,000 angstroms in various embodiments but other thicknesses are used in other embodiments.

Now turning to FIG. 1F, photoresist pattern 39 is formed over the structure of FIG. 1E and defines gate area 43. An etching operation is then carried out to successively remove unpatterned portions of upper silicon layer 35, dielectric 33 and silicon layer 33 to form a stacked floating gate transistor structure including a control gate formed of upper silicon layer 35 and a floating gate formed of silicon layer 3 and having a roughened upper surface 37. The etching operation is carried out upon areas outside of gate area 43 that are not covered by photoresist pattern 39.

After the etching operation is carried out and the photoresist removed, spacers 45 and a silicide portion 49 are formed over the stacked floating gate transistors in some embodiments such as shown in FIG. 1G. The control gate formed of upper silicon layer 35 is also coupled to and functions as a word line, WL. FIG. 1G also shows source and drain areas to which bit line BL and source line SL are coupled in some embodiments. Other stacked gate transistor arrangements are used in other embodiments.

FIGS. 2A and 2B illustrate other embodiments of an etched silicon upper surface such as produced using specks 21 according to various embodiments of the disclosure. In FIG. 2A, upper surface 40 includes pillars 41 that are generally rectangular in shape and have flat upper surfaces 42. Pillars 42 include a depth 44 that may range from 10 to 100% of the thickness of silicon layer 3. FIG. 2B shows curved upper surface 46 in which the upwardly extending silicon projections 48 of silicon layer 3 have rounded upper surfaces and silicon projections 48 include a height 50 that may range from 10 to 100% of thickness of silicon layer 3. In other embodiments, upper silicon surface 46 may be described an increased surface roughness. Surface roughness is a measure of the texture of a surface. It is quantified by the vertical deviations of a real surface from its ideal, i.e. completely flat, form. Amplitude parameters characterize the surface based on the vertical deviations of the roughness profile from the mean. In various embodiments of the disclosure, upper silicon surface 46 may be described as having a surface roughness greater than about 0.5 nm to 20 nm but greater surface roughness values are achieved in other embodiments.

FIGS. 3A-3F illustrate a sequence of processing operations used to form a split gate floating gate transistor according to another embodiment of a disclosure.

FIGS. 3A, 3B and 3C are identical to FIGS. 1A, 1B and 1C and are as previously described.

FIG. 3D illustrates a subsequent step in the processing sequence after the etching operation has been carried out upon the structure of FIG. 3C, to etch into silicon layer 3 to produce apices 25 and pillars 29. FIG. 3D is essentially the structure shown in FIG. 1D after specks 21 have been removed and photoresist pattern 39 has been formed in gate area 43. The processing sequence shown in FIGS. 3A-3C is also use to produce embodiments such as shown in FIGS. 2A and 2B, in various embodiments. Photoresist 39 is formed over top surface 37 including apices 25 of silicon layer 3.

An etching operation is then carried out at this stage to completely etch, i.e. remove, uncovered portions of silicon layer 3 and gate dielectric 5. After silicon layer 3 is patterned by etching, dielectric 53 is formed over patterned silicon layer 3 including over top surface 37 and along the opposed sides of silicon layer 3 and over the surface of laterally adjacent portions of substrate 1 according to the embodiment in which a split gate transistor is being formed. The patterned silicon layer 3 and dielectric 53 are shown in FIG. 3E.

In some embodiments, dielectric 53 is a conformal dielectric and includes a thickness chosen in conjunction with various device considerations. In some embodiments, dielectric 53 has a thickness ranging from about 2-100 nm, but other thicknesses are used in other embodiments. In some embodiments, dielectric 53 is an oxide or a nitride, and in other embodiments, dielectric layer 33 is an ONO (oxide/nitride/oxide) layer, including a native oxide, a nitride layer over the native oxide, and a top oxide layer having various thicknesses.

FIG. 3F shows the structure of FIG. 3E after an upper silicon layer has been formed over the structure shown in FIG. 3E, and patterned. Control gate 55 is a silicon material that is formed of polysilicon or other forms of silicon in various embodiments and may be doped or undoped. Control gate 55 extends over a portion of patterned silicon layer 3 serving as a floating gate. Control gate 55 also extends along sidewall 63 of patterned silicon layer 3 and over laterally adjacent portions of substrate 1. Control gate 55 is separated from patterned silicon layer 3 both on top and sides, by dielectric 53. Control gate 55 is coupled to a word line, WL, and includes upper silicide portion 59 in some embodiments. FIG. 3F also shows source and drain areas to which bit line, BL, and source line, SL, are coupled in some embodiments. The structure in FIG. 3F represents a split gate transistor, but other split gate transistor arrangements are used in other embodiments.

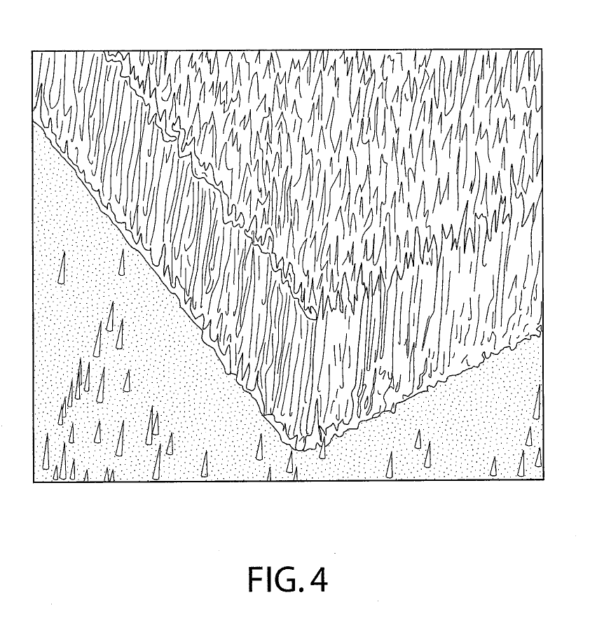

FIG. 4 is a plan view showing a patterned silicon portion such as a patterned silicon portion etched using the residual specks as masking objects according to various embodiments of the disclosure. FIG. 4 illustrates the sharp apices and pillars that form the silicon layer after etching. FIG. 4 illustrates an embodiment of roughened upper surface 37 as in FIGS. 1E-1G and FIGS. 3D-3E.

Various other densities of pillars and apices are achieved in other embodiments and are determined, at least in part by the plasma density and the RIE plasma etching conditions. It can be seen that the surface area of the top of the structure shown in FIG. 4 is much greater than the footprint of the structure of FIG. 4. In some embodiments, an increase in surface area of about 200% is achieved.

Further, the surface area of the roughened upper surface of silicon can take on other shapes as described above and as shown in FIGS. 1D, 2A and 2B. In some embodiments, the top surface of the etched silicon layer, e.g. top surface 37, top surface 40 and top surface 46, includes a surface area ranging from about 200% to about 400% of the area of the footprint of the silicon material, i.e. of the area defined by the lateral dimensions of the silicon layer.

According to one aspect, a method for forming a floating gate transistor is provided. The method comprises: forming a silicon layer over a gate dielectric layer over a substrate; coating a polymer layer over the silicon layer; treating the polymer layer with an RIE (reactive ion etch) process that removes portions of the polymer layer and creates a plurality of residual specks of polymer from the polymer layer on the silicon layer; etching the silicon layer using the plurality of residual specks as masking objects and thereby producing a plurality of sharp apices in the silicon layer; removing the residual specks; and forming a floating gate for a floating gate transistor, from the silicon layer.

In some embodiments, the polymer comprises photoresist and an upper surface of the etched silicon layer has a surface area being at least 300% of an area defined by lateral boundaries of the polysilicon layer.

In some embodiments, the polymer comprises one of a uv-curable photosetting polymer and a thermoplastic polymer.

In some embodiments, the residual specks include radii ranging from about several nanometers to about several hundred nanometers and the forming a floating gate comprises forming a further dielectric over the silicon layer after the etching, forming a polysilicon layer over the dielectric and patterning the polysilicon layer, the further dielectric and the silicon layer, the further dielectric being an oxide or a nitride and including a thickness of about 2-50 nm.

In some embodiments, the forming a floating gate comprises forming a further dielectric over the silicon layer after the etching, forming a polysilicon layer over the dielectric and patterning the polysilicon layer, the further dielectric and the silicon layer, the further dielectric being an ONO dielectric including a native oxide, a nitride layer and a top oxide layer.

In some embodiments, the floating gate transistor comprises a split gate floating gate transistor and the forming a floating gate comprises patterning the silicon layer, etching to remove uncovered portions of the silicon layer thereby forming a floating gate, forming a further dielectric over top and sides of the floating gate, then forming an upper control gate over a portion of the floating gate and laterally adjacent one side of the floating gate, wherein the further dielectric comprises an ONO dielectric including a native oxide, a nitride layer and a top oxide layer.

The method as in claim 1, wherein the treating includes the RIE process including a pressure of about 100-300 millitorr, a power of about 200-400 watts, a time of about 30 seconds to 2 minutes, a magnetic field of about 20-40 Gauss and HBr and Cl2 as etching gases.

In some embodiments, the sharp apices form tops of respective pillars having heights ranging from about 5 nm to about 300 nm.

In some embodiments, the silicon layer comprises polysilicon and the sharp apices form tops of respective pillars having heights ranging from about 50% to about 100% of an original height of the silicon layer.

According to another aspect, a method for forming a floating gate transistor is provided. The method comprises: forming a polysilicon layer over a gate dielectric layer over a substrate, the polysilicon layer having an upper surface with a first surface area; forming a sacrificial layer over the polysilicon layer; treating the sacrificial layer with an RIE (reactive ion etch) process that removes portions of the sacrificial layer and creates a plurality of residual specks from the sacrificial layer on the polysilicon layer; and etching the polysilicon layer using the plurality of residual specks as masking objects and thereby producing a second surface area of the polysilicon layer being greater than the first surface area.

In some embodiments, the second surface area is at least 300% of an area defined by lateral boundaries of the polysilicon layer and further comprising: removing the residual specks; forming a floating gate from the etched polysilicon layer and a dielectric on the floating gate; and forming a control gate over the floating gate.

In some embodiments, the sacrificial layer comprises an oxide layer and the dielectric comprises an ONO dielectric including a native oxide, a nitride layer, and a top oxide layer.

In some embodiments, the upper surface includes a plurality of polysilicon pillars.

In some embodiments, the second surface area is at least two times as great as the first surface area and the residual specks include radii ranging from about several nanometers to about several hundred nanometers.

In some embodiments, the sacrificial layer comprises one of a UV-curable photosetting polymer and a thermoplastic polymer.

In some embodiments, the upper surface has a surface area being at least 300% of an area defined by lateral boundaries of the polysilicon layer.

According to another aspect, a floating gate transistor comprises: a polysilicon layer disposed over a gate dielectric layer disposed over a substrate, the polysilicon layer having an upper surface including a plurality of polysilicon pillars; a further dielectric disposed over the polysilicon layer; and a control gate disposed over the further dielectric.

In some embodiments, the polysilicon pillars have apices and in some embodiments, the apices are sharp apices.

In some embodiments, the polysilicon pillars have flat top surfaces and a rectangular shape.

In some embodiments, the polysilicon pillars have rounded top surfaces.

In some embodiments, the upper surface has a surface area being at least 300% of an area defined by lateral boundaries of the polysilicon layer.

The preceding merely illustrates the principles of the disclosure. It will thus be appreciated that those of ordinary skill in the art will be able to devise various arrangements which, although not explicitly described or shown herein, embody the principles of the disclosure and are included within its spirit and scope. Furthermore, all examples and conditional language recited herein are principally intended expressly to be only for pedagogical purposes and to aid the reader in understanding the principles of the disclosure and the concepts contributed by the inventors to furthering the art, and are to be construed as being without limitation to such specifically recited examples and conditions. Moreover, all statements herein reciting principles, aspects, and embodiments of the disclosure, as well as specific examples thereof, are intended to encompass both structural and functional equivalents thereof. Additionally, it is intended that such equivalents include both currently known equivalents and equivalents developed in the future, i.e., any elements developed that perform the same function, regardless of structure.

This description of the exemplary embodiments is intended to be read in connection with the figures of the accompanying drawing, which are to be considered part of the entire written description. In the description, relative terms such as “lower,” “upper,” “horizontal,” “vertical,” “above,” “below,” “up,” “down,” “top” and “bottom” as well as derivatives thereof (e.g., “horizontally,” “downwardly,” “upwardly,” etc.) should be construed to refer to the orientation as then described or as shown in the drawing under discussion. These relative terms are for convenience of description and do not require that the apparatus be constructed or operated in a particular orientation. Terms concerning attachments, coupling and the like, such as “connected” and “interconnected,” refer to a relationship wherein structures are secured or attached to one another either directly or indirectly through intervening structures, as well as both movable or rigid attachments or relationships, unless expressly described otherwise.

Although the disclosure has been described in terms of exemplary embodiments, it is not limited thereto. Rather, the appended claims should be construed broadly, to include other variants and embodiments of the disclosure, which may be made by those of ordinary skill in the art without departing from the scope and range of equivalents of the disclosure.

1. A method for forming a floating gate transistor, said method comprising:
forming a silicon layer over a gate dielectric layer over a substrate;
coating a polymer layer over said silicon layer;
treating said polymer layer with an RIE (reactive ion etch) process that removes portions of said polymer layer and creates a plurality of residual specks of polymer from said polymer layer on said silicon layer;
etching said silicon layer using said plurality of residual specks as masking objects and thereby producing a plurality of apices in said silicon layer;
removing said residual specks; and
forming a floating gate for a floating gate transistor, from said silicon layer.

2. The method as in claim 1, wherein said polymer comprises photoresist and an upper surface of said etched silicon layer has a surface area being at least 300% of an area defined by lateral boundaries of said silicon layer.

3. The method as in claim 1, wherein said polymer comprises one of a uv-curable photosetting polymer and a thermoplastic polymer.

4. The method as in claim 1, wherein said residual specks include radii ranging from about several nanometers to about several hundred nanometers and said forming a floating gate comprises forming a further dielectric over said silicon layer after said etching, forming a polysilicon layer over said dielectric and patterning said polysilicon layer, said further dielectric and said silicon layer, said further dielectric being an oxide or a nitride and including a thickness of about 2-50 nm.

5. The method as in claim 1, wherein said forming a floating gate comprises forming a further dielectric over said silicon layer after said etching, forming a polysilicon layer over said dielectric and patterning said polysilicon layer, said further dielectric and said silicon layer, said further dielectric being an ONO dielectric including a native oxide, a nitride layer and a top oxide layer.

6. The method as in claim 1, wherein said floating gate transistor comprises a split gate floating gate transistor and said forming a floating gate comprises patterning said silicon layer, etching to remove uncovered portions of said silicon layer thereby forming a floating gate, forming a further dielectric over top and sides of said floating gate, then forming an upper control gate over a portion of said floating gate and laterally adjacent one side of said floating gate, wherein said further dielectric comprises an ONO dielectric including a native oxide, a nitride layer and a top oxide layer.

7. The method as in claim 1, wherein said treating includes said RIE process including a pressure of about 100-300 millitorr, a power of about 200-400 watts, a time of about 30 seconds to 2 minutes, a magnetic field of about 20-40 Gauss and HBr and Cl₂ as etching gases.

8. The method as in claim 1, wherein said apices form tops of respective pillars having heights ranging from about 5 nm to about 300 nm.

9. The method as in claim 1, wherein said silicon layer comprises polysilicon and said apices form tops of respective pillars having heights ranging from about 50% to about 100% of an original height of said silicon layer.

10. A method for forming a floating gate transistor, said method comprising:
forming a polysilicon layer over a gate dielectric layer over a substrate, said polysilicon layer having an upper surface with a first surface area;
forming a sacrificial layer over said polysilicon layer;
treating said sacrificial layer with an RIE (reactive ion etch) process that removes portions of said sacrificial layer and creates a plurality of residual specks from said sacrificial layer on said polysilicon layer; and
etching said polysilicon layer using said plurality of residual specks as masking objects and thereby producing a second surface area of said polysilicon later being greater than said first surface area.

11. The method as in claim 10, wherein said second surface area is at least 300% of an area defined by lateral boundaries of said polysilicon layer and further comprising:
removing said residual specks;
forming a floating gate from said etched polysilicon layer and a dielectric on said floating gate; and
forming a control gate over said floating gate.

12. The method as in claim 10, wherein said sacrificial layer comprises an oxide layer and said dielectric comprises an ONO dielectric including a native oxide, a nitride layer, and a top oxide layer.

13. The method as in claim 10, wherein said upper surface includes a plurality of polysilicon pillars.

14. The method as in claim 13, wherein said polysilicon pillars include apices.

15. The method as in claim 10, wherein said second surface area is at least 300% of said first surface area, said residual specks include radii ranging from about several nanometers to about several hundred nanometers and said sacrificial layer comprises one of a UV-curable photosetting polymer and a thermoplastic polymer.

16-20. (canceled)

21. The method as in claim 1, wherein said polymer comprises a thermoplastic polymer.

22. The method as in claim 10, wherein said sacrificial layer comprises a thermoplastic polymer.

23. The method as in claim 1, wherein said forming a floating gate comprises patterning said silicon layer, etching to remove uncovered portions of said silicon layer thereby forming a floating gate, forming a further dielectric over top and sides of said floating gate, then forming an upper control gate over a portion of said floating gate, wherein said further dielectric comprises an ONO dielectric including a native oxide, a nitride layer and a top oxide layer.

24. The method as in claim 11, wherein said dielectric on said floating gate comprises an ONO dielectric including a native oxide, a nitride layer and a top oxide layer, and said forming an upper silicon control gate over a portion of said floating gate.

25. The method as in claim 9, wherein said polymer comprises a uv-curable photosetting polymer.
